(19) United States
(12) Patent Application Publication
(10) Pub. No.: US 2024/0364991 A1
(43) Pub. Date: Oct. 31, 2024

(54) CAMERA ASSEMBLY AND ELECTRONIC DEVICE

(71) Applicant: SAMSUNG ELECTRONICS CO., LTD., Suwon-si (KR)

(72) Inventor: Wenjun WANG, Suzhou (CN)

(73) Assignee: SAMSUNG ELECTRONICS CO., LTD., Suwon-si (KR)

(21) Appl. No.: 18/608,252

(22) Filed: Mar. 18, 2024

(30) Foreign Application Priority Data
Apr. 27, 2023 (CN) 202310473295.3

(51) Int. Cl. H04N 23/55; H04N 23/56

(52) U.S. Cl. CPC H04N 23/55; H04N 23/56

(57) ABSTRACT

A camera assembly includes: a circuit board; a bracket on the circuit board and including an opening on a first surface of the bracket; a light emitter on the bracket, configured to emit light to an object; and a lens assembly configured to transmit light reflected by the object, passing through the opening in the bracket, and a portion of the lens assembly being inside the bracket, wherein the light emitter is coaxial with the lens assembly.

### CROSS-REFERENCE TO RELATED APPLICATION

This application claims priority to the Chinese Patent Application No. 202310473295.3 filed on Apr. 27, 2023 in the China National Intellectual Property Administration, the disclosure of which is incorporated by reference herein in its entirety.

### BACKGROUND

### 1. Field

The disclosure relates to a camera assembly, and more particularly, to a time-of-flight (TOF) camera assembly.

### 2. Description of Related Art

Time-of-flight (TOF) cameras are widely used in face recognition, gesture recognition, distance measurement, and three-dimensional (3D) modeling fields due to their ability to output 3D image information. In recent years, they have been widely used in the field of consumer electronic products.

However, with the development of thinner and lighter consumer electronic products, the miniaturization of consumer electronic product components have become a development trend. The camera is an important component in consumer electronic products and the industry is concerned with the achievement of the miniaturization of the camera module package.

### SUMMARY

The disclosure provides a camera assembly having a reduced size and an improved effective field of view.

In accordance with an aspect of the disclosure, a camera assembly includes a circuit board; a bracket on the circuit board, the bracket including an opening on a first surface of the bracket; a light emitter on the bracket, the light emitter configured to emit light to an object; and a lens assembly configured to transmit light reflected by the object and passing through the opening in the bracket, a portion of the lens assembly being inside the bracket, wherein the light emitter is coaxial with the lens assembly.

The disclosure enables coaxial arrangement of the light emitter and the lens assembly by redesigning the light emitter and the lens assembly of the TOF camera assembly. Thus, the camera assembly according to example embodiments of the disclosure may not only have a reduced size, enabling miniaturized packaging of the camera assembly while saving raw materials and thus reducing costs, but also may have an improved effective field of view.

### BRIEF DESCRIPTION OF DRAWINGS

The above and other aspects of the disclosure will become more apparent and more easily understood by the following detailed description in conjunction with the accompanying drawings.

FIG. 1 is a diagram showing a time-of-flight (TOF) camera assembly according to the prior art.

FIG. 2 is a diagram showing a camera assembly according to embodiments of the disclosure.

FIG. 3 is an exploded diagram showing a camera assembly according to embodiments of the disclosure.

FIG. 4 is a diagram showing an effective field of view of a TOF camera assembly according to the prior art.

FIG. 5 is a diagram showing an effective field of view of a TOF camera assembly according to embodiments of the disclosure.

FIG. 6 is a diagram showing an electronic device including a TOF camera assembly according to embodiments of the disclosure.

Throughout the drawings and the detailed description, the same figure reference numerals will be understood to refer to the same elements, features and structures unless described or provided otherwise. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween. Likewise, similar expressions, for example, “between” and “immediately between,” and “adjacent to” and “immediately adjacent to,” are also to be construed in the same way. As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Unless otherwise defined, all terms, including technical and scientific terms, used herein have the same meaning as commonly understood by one of ordinary skill in the art to which this disclosure pertains and based on an understanding of the disclosure. Terms, such as those defined in commonly used dictionaries, are to be interpreted as having a meaning that is consistent with their meaning in the context of the relevant art and the disclosure and are not to be interpreted in an idealized or overly formal sense unless expressly so defined herein. The use of the term “may” herein with respect to an example or embodiment (e.g., as to what an example or embodiment may include or implement) means that at least one example or embodiment exists where such a feature is included or implemented, while all example embodiments are not limited thereto.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. Like numerals refer to like elements throughout.

Spatially relative terms, such as “over,” “above,” “on,” “upper,” “below,” “under,” “beneath,” “lower,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

For the sake of brevity, conventional elements to semiconductor devices may or may not be described in detail herein for brevity purposes.

Example embodiments will be described below in detail with reference to the accompanying drawings.

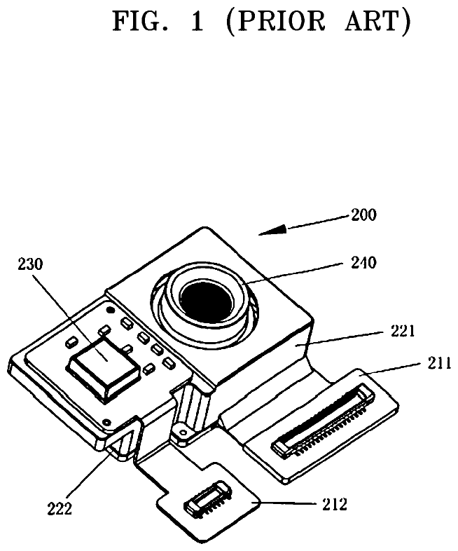

FIG. 1 is a diagram showing a time-of-flight (TOF) camera assembly 200 according to the prior art.

Referring to FIG. 1, the TOF camera assembly 200 may include: a first circuit board 211, a second circuit board 212, a first bracket 221, a second bracket 222, a light emitter 230, and a lens assembly 240.

The first circuit board 211 may support the first bracket 221, the light emitter 230, and the lens assembly 240, and the first bracket 221 and the lens assembly 240 may be mounted or provided on the first circuit board 211. The second circuit board 212 may support the second bracket 222, and the second bracket 222 may be mounted or provided on the second circuit board 212. The first bracket 221 may be provided on the first circuit board 211 and may include an opening provided on a first surface of the first bracket 221. The second bracket 222 may be provided on a side of (e.g., next to) the first bracket 221. The light emitter 230 may be provided on the second bracket 222. That is, the light emitter 230 may be provided at a side portion of the lens assembly 240. In addition, a shape of the portion of the light emitter 230 for emitting light may be rectangular. The lens assembly 240 may pass through the opening of the first bracket 221, and a portion of the lens assembly 240 is provided inside the first bracket 221. When being used, a light emitted to an object by the light emitter 130 and reflected by the object may be received by a light receiver through the lens assembly 240. Thus, the TOF camera assembly 200 according to the prior art is large in size, such that it is difficult to miniaturize and slim down an electronic device including the TOF camera assembly 200 according to the prior art.

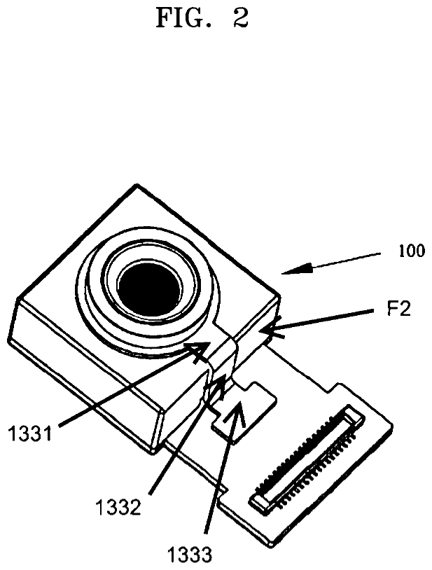

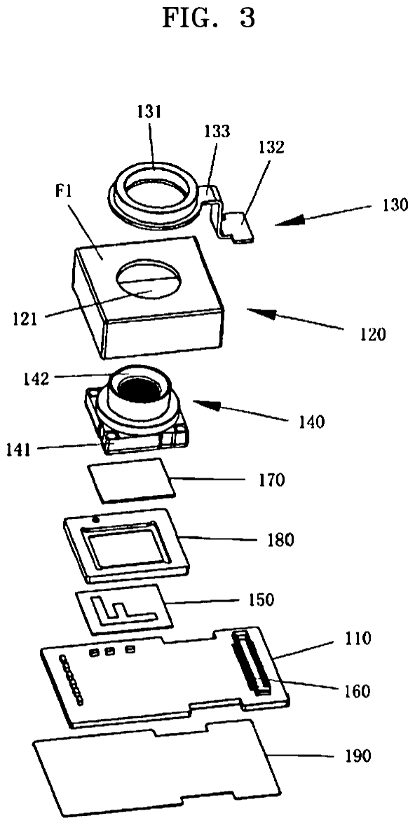

FIG. 2 is a diagram showing a camera assembly according to embodiments of the disclosure. FIG. 3 is an exploded diagram showing a camera assembly according to embodiments of the disclosure.

The camera assembly 100 according to embodiments of the disclosure may be a TOF camera assembly (also referred to as a depth camera) that may be used to output three-dimensional (3D) image information including depth information. In an example, referring to FIGS. 2 and 3, the camera assembly 100 may include: a circuit board 110, a bracket 120, a light emitter 130, and a lens assembly 140.

The circuit board 110 may support various components of the camera assembly 100. For example, the circuit board 110 may support the bracket 120, the light emitter 130, and the lens assembly 140. The bracket 120, the light emitter 130, and the lens assembly 140 may be mounted or provided on the circuit board 110. The circuit board 110 may provide circuits for electrically connecting the various components supported by the circuit board 110 to each other. The circuit board 110 may be a printed circuit board (PCB). In addition, the circuit board 110 may have any shape, according to needs.

The bracket 120 may support one or more of the various components mounted or provided on the circuit board 110, and may also accommodate one or more of the various components mounted or provided on the circuit board 110 to protect the one or more of the various components mounted or provided on the circuit board 110 from external shocks. The bracket 120 may be provided on the circuit board 110 and may include an opening 121 provided on a first surface F1 of the bracket 120. In an example, the first surface F1 of the bracket 120 may be parallel to a surface of the circuit board 110 mounted or provided with the bracket 120, and a shape of the opening 121 may be circular. However, it should be understood that the disclosure is not limited thereto. For example, the first surface F1 of the bracket 120 may be any surface of the bracket 120 and the shape of the opening 121 may be any shape, according to needs.

The light emitter 130 may be used to emit light to the object and is provided on the bracket 120. Since an infrared light has a good ability to penetrate clouds, in an example, the light emitted by the light emitter 130 may be an infrared light or a near-infrared light to improve the accuracy of the measurement. In addition, unlike the TOF camera assembly 200 according to the prior art of FIG. 1, the light emitter 130 may be coaxial with the lens assembly 140 according to embodiments of the disclosure. For example, the light emitter 130 may have an annulus shape surrounding the lens assembly 140, and the light emitter 130 having the annulus shape may be coaxial with the lens assembly 140 and the opening 121. Thus, the camera assembly 100 according to embodiments of the disclosure may have a reduced size, enabling miniaturized packaging of the camera assembly 100 while saving raw materials and thereby reducing costs.

In an example, as shown in FIGS. 2 and 3, the light emitter 130 may include: an emitter body 131, an emitter interface 132, and an emitter cable 133. As a uniform surface light source, the emitter body 131 may be provided on the bracket 120 and include a light source for emitting light (e.g., an infrared light or a near-infrared light) to an object. A shape of the emitter body 131 may be an annulus shape that surrounds the lens assembly 140 and matches a size of the lens assembly 140, and the emitter body 131 may be provided on a first surface F1 of the bracket 120. For example, an inner diameter of the annular shape of the emitter body 131 may match the size of the lens assembly 140 and a diameter of the opening 121. Thus, the emitter body 131 may smoothly allow the lens assembly to pass through the annular shaped light emitter 130, and the annular shape of the emitter body 131 may serve as a light emitting portion of a uniform surface light source. The emitter interface 132 may be used to receive signals and power and is provided on the circuit board 110. The emitter interface 132 may be provided on the circuit board 110 outside the bracket 120. For example, the emitter interface 132 may be provided on an area of the circuit board 110 that is different from an area where the bracket 120 is provided. The emitter cable 133 may be used to electrically connect the emitter body 131 to the emitter interface 132. For example, a first portion 1331 of the emitter cable 133 may be provided on the first surface F1 of the bracket 120, a second portion 1332 of the emitter cable 133 may be provided on a second surface F2 of the bracket 120 adjacent to the first surface F1, and a third portion 1333 of the emitter cable 133 may be provided on the circuit board 110 outside the bracket 120.

The lens assembly 140 may be used to transmit light reflected by the object, and pass through the opening 121 of the bracket 120, and a portion of the lens assembly 140 is provided inside the bracket 120. In an example, as shown in FIG. 3, the lens assembly 140 may include: a lens base 141 and a lens 142. The lens base 141 may be provided inside the bracket 120 and may support the lens 142. The lens 142 may be provided on the lens base 141, protrude from the lens base 141, and pass through the opening 121 of the bracket 120. The lens 142 may be cylindrical in shape, and a diameter of the lens 142 may match a diameter of the opening 121 of the bracket 120 such that the lens 142 may pass through the opening 121. In addition, the diameter of the lens 142 may also match a diameter of the opening 121 that matches the annular inner diameter of the light emitter 130, such that the lens 142 may pass smoothly through the opening 121 and the light emitter 130. In addition, in an example, the lens 142 may be a cylindrical shape with steps, such that lens 142 can be easily positioned.

In an example, as shown in FIG. 2, the camera assembly 100 may also include a light receiver 150. The light receiver 150 may be used to receive light reflected by the object and is provided below the lens assembly 140. That is, the light receiver 150 may be used to receive light emitted to the object by the light emitter 130 and reflected by the object. Unlike the TOF camera assembly 200 according to the prior art of FIG. 1, according to embodiments of the disclosure, the light receiver 150 may be coaxial with the lens assembly 140, or a central axis of the light receiver 150 may be coaxial with an optical axis of the lens assembly 140, or a surface of the light receiver 150 may be perpendicular to the optical axis of the lens assembly 140. Further, unlike the TOF camera assembly 200 according to the prior art of FIG. 1, according to embodiments of the disclosure, the light receiver 150 may also be coaxial with the light emitter 130, or the central axis of the light receiver 150 may also be coaxial with the central axis of the light emitter 130, or the surface of the light receiver 150 may be perpendicular to the central axis of the light emitter 130. Thus, the light receiver 150 may be provided directly below the lens assembly 140, the opening 121, and the light emitter 130. That is, all of the light receiver 150, the lens assembly 140, the opening 121 and the light emitter 130 may be provided coaxially. The surface of the light receiver 150 may be parallel to the surface of the light emitter 130. The light emitter 150 and the light emitter 130 may share the circuit board 110 and be electrically connected to the circuit board 110. Thus, the camera assembly 100 according to the embodiments of the disclosure may have a reduced size, enabling miniaturized packaging of the camera assembly 100 while saving raw materials and thereby reducing costs.

In an example, as shown in FIG. 3, camera assembly 100 may also include a connector 160. The connector 160 may be used to communicate with one or more devices external to camera assembly 100 and is electrically connected to the circuit board 110. For example, the connector 160 may be used to communicate with other components in an electronic device that includes the camera assembly 100. The light emitter 150 and the light emitter 130 share the connector 160 and communicate with one or more devices external to the camera assembly 100 through the connector 160.

In an example, as shown in FIG. 3, the camera assembly 100 may also include a light filter 170 and a base 180. The light filter 170 may be provided between the lens assembly 140 and the light receiver 150, and may filter undesired light. The base 180 may be provided between the light filter 170 and the light receiver 150 and support the light filter 170 and the lens assembly 140. In an example, the base 180 may have a rectangular opening, the light filter 170 may be provided on one surface of the base 180, the light receiver 150 may be provided on another surface of the base 180, and light emitted to the object by the light emitter 130 and reflected by the object may be received by the light receiver 150 through the rectangular opening of the base 180.

In an example, as shown in FIG. 3, the camera assembly 100 may also include a shielding cover 190. For example, the shielding cover 190 may cover a surface of the circuit board on which the above components are not mounted, thereby shielding against external interference.

While the embodiment of FIG. 3 shows the light receiver 150, the light filter 170, and the base 180 being included inside the camera assembly 100, it should be understood, the disclosure is not limited thereto. For example, one or more of the light receiver 150, the filter 170 and the base 180 may be provided outside the camera assembly 100.

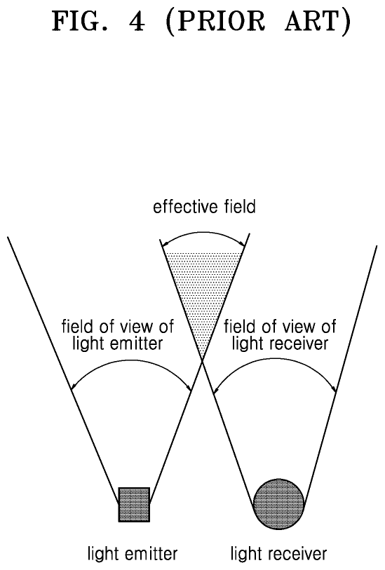

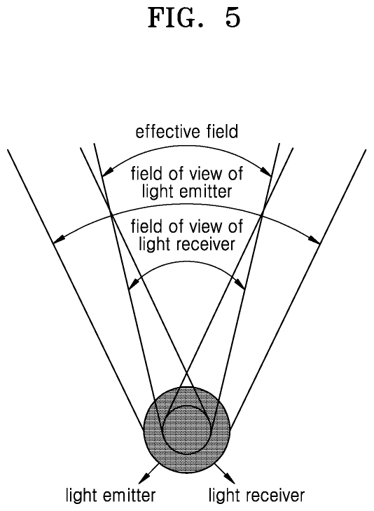

FIG. 4 is a diagram showing an effective field of view of a TOF camera assembly 200 according to the prior art. FIG. 5 is a diagram showing an effective field of view of a TOF camera assembly 100 according to embodiments of the disclosure.

Referring to FIG. 4, in the TOF camera assembly 200 according to the prior art, the effective field of view of the TOF camera assembly 200 as an overlapping field of view between the field of view of the light emitter 230 and the field of view of the light receiver 250 is small because the light emitter 230 is not coaxial with the light receiver 250. However, referring to FIG. 5, in the camera assembly 100 according to embodiments of the disclosure, the effective field of view of the camera assembly 100 as an overlapping field of view between the field of view of the light emitter 130 and the field of view of the light receiver 150 is larger because the light emitter 130 is coaxial with the light receiver 150. Thus, the camera assembly 100 according to embodiments of the disclosure may have not only a reduced size but also an improved effective field of view.

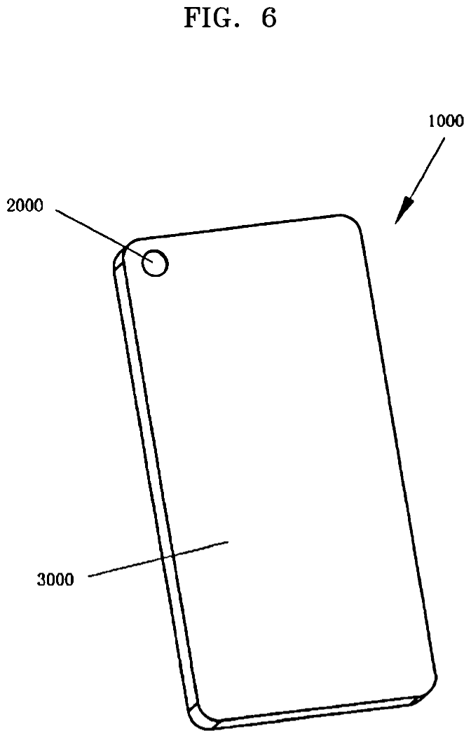

FIG. 6 is a diagram showing an electronic device including a TOF camera assembly 1000 according to embodiments of the disclosure.

Referring to FIG. 6, the disclosure provides an electronic device 1000. Specifically, the electronic device 1000 may be any of various types of computer system device that is mobile or portable and performs wireless communication (only one form is shown as an example in FIG. 6). Specifically, the electronic device 1000 can be a mobile or smart phone, portable gaming devices, laptops, PDAs, portable Internet devices, music players, data storage device, other handheld devices, and the like. In addition, the electronic device 1000 can be other wearable devices that require to be charged (e.g., smart bracelets, smart necklaces, head-mounted devices (HMIDs) such as smart headphones, or smart watches).

The electronic device 1000 may also be any one of a plurality of electronic devices, the plurality of electronic devices including, but not limited to, cellular telephones, smart phones, other wireless communication devices, personal digital assistants, audio players, other media players, music recorders, video recorders, other media recorders, radios, medical devices, vehicle transport devices, calculators, programmable remote controls, pagers, laptops computers, desktop computers, printers, netbook computers, personal digital assistants (PDAs), portable multimedia players (PMPs), motion picture expert groups (MPEG-1 or MPEG-2) audio layer 3 (MP3) players, portable medical devices, and digital cameras and their combinations and other equipment.

In some cases, the electronic device 1000 can perform a variety of functions (e.g., play music, display video, store pictures, and receive and send phone calls). If desired, electronic device 1000 can be, for example, a cellular phone, media player, other handheld device, wristwatch device, pendant device, handset device, or other compact and portable device.

The electronic device 1000 may include a camera assembly 2000 and a housing 3000, the camera assembly 2000 may be housed in the housing 3000 and partially exposed outside the housing 3000. The housing 3000 may be used to protect the camera assembly 2000. For example, the electronic device 1000 may be a cell phone, and the camera assembly 2000 may be provided on the housing 3000 (i.e., a back cover) of the cell phone. In addition, the camera assembly 2000 may correspond to the camera assembly 100 described above with reference to FIGS. 2 and 3.

While the disclosure has been specifically shown and described with reference to embodiments, it should be understood by those skilled in the art that various changes in form and detail may be made thereto without departing from the spirit and scope of the disclosure as defined by the claims.

What is claimed is:

1. A camera assembly comprising:
a circuit board;
a bracket on the circuit board, the bracket comprising an opening on a first surface of the bracket;
a light emitter on the bracket, the light emitter configured to emit light to an object; and
a lens assembly configured to transmit light reflected by the object and passing through the opening in the bracket, a portion of the lens assembly being inside the bracket,
wherein the light emitter is coaxial with the lens assembly.

2. The camera assembly of claim 1, wherein the light emitter has an annulus shape surrounding the lens assembly.

3. The camera assembly of claim 2, wherein the light emitter comprises:
an emitter body on the bracket, the emitter body comprising a light source configured to emit light to the object;
an emitter interface on the circuit board, the emitter interface configured to receive signals and power; and
an emitter cable configured to electrically connect the emitter body to the emitter interface.

4. The camera assembly of claim 3, wherein a shape of the emitter body is a circular shape that surrounds the lens assembly and matches a size of the lens assembly, and
wherein the emitter body is on the first surface of the bracket.

5. The camera assembly of claim 3, wherein the emitter interface is on the circuit board outside the bracket.

6. The camera assembly of claim 3, wherein a first portion of the emitter cable is on the first surface of the bracket, a second portion of the emitter cable is on a second surface of the bracket adjacent to the first surface, and a third portion of the emitter cable is on the circuit board outside the bracket.

7. The camera assembly of claim 1, wherein the lens assembly comprises:
a lens base inside the bracket; and
a lens on the lens base, protruding from the lens base, and passing through the opening of the bracket.

8. The camera assembly of claim 1, further comprising:
a light receiver below the lens assembly, the light receiver configured to receive light reflected by the object.

9. The camera assembly of claim 8, wherein a surface of the light receiver is perpendicular to an optical axis of the lens assembly.

10. The camera assembly of claim 8, wherein a surface of the light receiver is perpendicular to a central axis of the light emitter.

11. The camera assembly of claim 8, wherein the light receiver and light emitter share the circuit board and are electrically connected to the circuit board.

12. The camera assembly of claim 8, further comprising:
a connector electrically connected to the circuit board, the connector configured to communicate with a device external to the camera assembly,
wherein the light receiver and light emitter share the connector and are configured to communicate with the device external to the camera assembly by way of the connector.

13. The camera assembly of claim 8, further comprising:
a light filter between the lens assembly and the light receiver; and
a base between the light filter and the light receiver, the base supporting the light filter and the lens assembly.

14. An electronic device comprising the camera assembly of claim 1.
